(19) United States
(12) Patent Application Publication
(10) Pub. No.: US 2022/0301857 A1
(43) Pub. Date: Sep. 22, 2022

(54) SYSTEMS AND METHODS FOR SELECTIVELY ETCHING FILMS

(71) Applicant: ASM IP Holding B.V., Almere (NL)

(72) Inventors: Fei Wang, Phoenix, AZ (US); Woo Jung Shin, Chandler, AZ (US); Aditya Walimbe, Tempe, AZ (US)

(21) Appl. No.: 17/697,056

(22) Filed: Mar. 17, 2022

Related U.S. Application Data
(60) Provisional application No. 63/162,878, filed on Mar. 18, 2021.
(60) Provisional application No. 63/163,107, filed on Mar. 19, 2021.

(51) Int. Cl. H01L 21/02; B08B 7/00

(52) U.S. Cl. CPC H01L 21/02057; H01L 21/02532; B08B 7/00

(57) ABSTRACT

A method of precleaning a substrate includes supporting a substrate with silicon oxide on its surface within a reaction chamber of a semiconductor processing system and flowing a halogen-containing reactant and a hydrogen-containing reactant into the reaction chamber. A first preclean material is formed from the halogen-containing reactant, the hydrogen-containing reactant, and a first portion of the silicon oxide on the surface of the substrate. Additional halogen-containing reactant is flowed into the reaction chamber without flowing additional hydrogen-containing reactant into the reaction chamber, and a second preclean material is formed from the additional halogen-containing reactant and a second portion of the silicon oxide on the surface of the substrate. Methods of forming structures on substrates and semiconductor processing systems are also described.

### CROSS-REFERENCE TO RELATED APPLICATIONS

This application claims priority to and the benefit of U.S. Provisional Patent Application No. 63/162,878, filed Mar. 18, 2021 and entitled “FILM DEPOSITION SYSTEMS AND METHODS,” and U.S. Provisional Patent Application No. 63/163,107, filed Mar. 19, 2021 and entitled “SYSTEMS AND METHODS FOR SELECTIVELY ETCHING FILMS,” which are hereby incorporated by reference herein to the extent that they do not conflict with the present disclosure.

### FIELD OF INVENTION

The present disclosure generally relates to precleaning substrates. More particularly, the present disclosure relates to precleaning substrates and forming structures on precleaned substrates, such as during the fabrication of semiconductor devices.

### BACKGROUND OF THE DISCLOSURE

Material layers are commonly deposited onto substrates during the fabrication of semiconductor devices, such as integrated circuits and power electronics. For example, amorphous, polycrystalline, or monocrystalline material layers may be deposited onto semiconductor substrates, such as silicon wafers. Such material layers are generally deposited using physical techniques, like sputtering, or chemical techniques, such as chemical vapor deposition or atomic layer deposition. Monocrystalline material layers are typically deposited using epitaxial techniques.

During the formation of some material layers, intervening materials formed on the substrate surface may interfere with the deposition of a material layer onto the substrate. For example, native oxides present on the substrate surface may cause defects to develop within a material layer during deposition of a material layer on the substrate. Intervening materials may form on substrate surfaces due to exposure to oxygen during substrate handling, as may occur during substrate transfer between various fabrication systems. Intervening materials may also form on substrate surfaces upon exposure to residual oxidizing agents that may be present within certain fabrication systems. Such interning materials may require removal prior to depositing a desired material layer onto the surface of the substrate.

Such methods and systems have generally been considered suitable for their intended purpose. However, there remains a need in the art for improved precleaning methods, methods of forming structures on substrates, and semiconductor processing systems. The present disclosure provides a solution to this need.

### SUMMARY OF THE DISCLOSURE

A method of precleaning a substrate is provided. The method includes supporting a substrate with silicon oxide on its surface within a reaction chamber of a semiconductor processing system. A halogen-containing reactant and a hydrogen-containing reactant are flowed into the reaction chamber. A first preclean material formed from the halogen-containing reactant, the hydrogen-containing reactant, and a first portion of the silicon oxide on the surface of the substrate. Additional halogen-containing reactant is flowed into the reaction chamber without flowing additional hydrogen-containing reactant into the reaction chamber and a second preclean material formed from the additional halogen-containing reactant and a second portion of the silicon oxide on the surface of the substrate.

In certain examples, the method may include epitaxially depositing a silicon-containing material layer onto the precleaned surface of the substrate.

In certain examples, flowing the halogen-containing reactant and the hydrogen-containing reactant into the reaction chamber may include flowing anhydrous hydrogen fluoride (HF) and at least one of ammonia (NH₃), hydrazine (N₂H₄), methanol (CH₃OH), isopropanol (C₃H₈O), or acetic acid (C₂H₄O₂) into the reaction chamber.

In certain examples, flowing the additional halogen-containing reactant into the reaction chamber may include flowing anhydrous hydrogen fluoride (HF) into the reaction chamber without flowing additional hydrogen-containing reactant into the reaction chamber.

In certain examples, forming the first preclean material may include forming ammonium hexafluorosilicate ((NH₄)₂SiF₆) and water (H₂O) from the halogen-containing reactant, the hydrogen-containing reactant, and the silicon oxide on the surface of the substrate.

In certain examples, forming the second preclean material from the halogen-containing reactant and the silicon oxide may include forming silicon fluoride (SiF4) and water (H₂O) from the halogen-containing reactant and the silicon oxide on the surface of the substrate.

In certain examples, the method may include sublimating the first preclean material from the surface of the substrate subsequent to forming the second preclean material from the additional halogen-containing reactant and the silicon oxide on the surface of the substrate.

In certain examples, the substrate may be a patterned substrate having a two or more recesses or trenches thereon with a high aspect ratio.

In certain examples, forming the second preclean material may include initiating formation of the second preclean material using water (H₂O) formed during the formation of the first preclean material.

In certain examples, the method may include flowing an inert gas into the reaction chamber prior to flowing the additional halogen-containing reactant into the reaction chamber and subsequent to forming the first preclean material from the halogen-containing reactant and the hydrogen-containing reactant.

In certain examples, the method may include sweeping residual halogen-containing reactant from the reaction chamber prior to flowing the additional halogen-containing reactant into the reaction chamber.

In certain examples, the method may include sweeping residual hydrogen-containing reactant from the reaction chamber prior to flowing the additional halogen-containing reactant into the reaction chamber.

In certain examples, forming the first preclean material may include etching the silicon oxide to a first depth; forming the second preclean material may include etching the silicon oxide to a second depth; and a ratio of the second depth to the first depth may be between about 2:1 and about 50:1, or is between about 3:1 and about 30:1, or is between about 5:1 and about 20:1.

In certain examples, the method may include ceasing formation of the first preclean material by purging the reaction chamber prior to flowing the additional halogen-containing reactant into the reaction chamber.

A method of forming a structure is provided. The method includes precleaning a substrate using a precleaning method as described above. The substrate is a patterned substrate with two or more recesses or trenches having a high aspect ratio. The first preclean material is sublimated from the surface of the substrate subsequent to forming the second preclean material from the additional halogen-containing reactant and silicon oxide on the surface of the substrate. A silicon-containing material layer is epitaxially deposited onto the surface of the substrate subsequent to sublimating the first preclean material from the surface of the substrate.

In certain examples, flowing the halogen-containing reactant and the hydrogen-containing reactant into the reaction chamber may include flowing anhydrous hydrogen fluoride (HF) and ammonia (NH₃) into the reaction chamber. Flowing the additional halogen-containing reactant into the reaction chamber may include flowing anhydrous hydrogen fluoride (HF) into the reaction chamber without flowing additional hydrogen-containing reactant into the reaction chamber.

In certain examples, forming the first preclean material may include forming ammonium hexafluorosilicate ((NH₄)₂SiF₆) and water (H₂O) from the halogen-containing reactant, the hydrogen-containing reactant, and the silicon oxide on the surface of the substrate. Forming the second preclean material from the halogen-containing reactant and the silicon oxide may include forming silicon fluoride (SiF₄) and water (H₂O) from the halogen-containing reactant and the silicon oxide on the surface of the substrate.

A semiconductor processing system is provided. The semiconductor processing system includes a gas system configured to flow a halogen-containing reactant and a hydrogen-containing reactant to a reaction chamber, a reaction chamber connected to the gas system and configured to support a substrate with silicon oxide on its surface, and a controller. The controller is operatively associated with the gas system and the reaction chamber. The controller is further responsive to instruction recorded on a non-transitory machine-readable medium to support a substrate having silicon oxide on its surface within the reaction chamber; flow a halogen-containing reactant and a hydrogen-containing reactant into the reaction chamber; and form a first preclean material from the halogen-containing reactant, the hydrogen-containing reactant, and a first portion of the silicon oxide on the surface of the substrate. The instructions further cause the controller to flow additional halogen-containing reactant without additional hydrogen-containing reactant into the reaction chamber and form a second preclean material from the additional halogen-containing reactant and a second portion of the silicon oxide on the surface of the substrate.

In certain examples, the instructions may further cause the controller to flow anhydrous hydrogen fluoride (HF) and ammonia (NH₃) into the reaction chamber to form the first preclean material, and flow additional anhydrous hydrogen fluoride (HF) into the reaction chamber without flowing additional ammonia into the reaction chamber.

In certain examples, the instructions may further cause the controller to form ammonium hexafluorosilicate ((NH₄)₂SiF₆) as the first preclean material in conjunction with and water (H₂O) from the halogen-containing reactant, the hydrogen-containing reactant, and the silicon oxide on the surface of the substrate; cease formation of the ammonium hexafluorosilicate ((NH₄)₂SiF₆) by purging the reaction chamber prior to flowing the additional anhydrous hydrogen fluoride (HF) into the reaction chamber; form silicon fluoride (SiF₄) as the second preclean material in conjunction with water (H₂O) from the halogen-containing reactant and the silicon oxide on the surface of the substrate; and sublimate the ammonium hexafluorosilicate ((NH₄)₂SiF₆) from the surface of the substrate subsequent to forming the silicon fluoride (SiF₄) using the anhydrous hydrogen fluoride (HF) and silicon oxide on the surface of the substrate.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system in accordance with the present disclosure, showing a reaction chamber operatively associated with a controller and configured to preclean a substrate supported within the reaction chamber;

FIGS. 2-4 are block diagrams of a method of precleaning a substrate in accordance with the present disclosure, showing operations of the method according to an illustrative and non-limiting examples of the method;

FIGS. 5A-5D are cross-sectional side views of a substrate with silicon oxide on its surface, sequentially showing the silicon oxide being removed from the surface of the substrate according to an illustrate and non-limiting example of the method;

FIG. 6 is a block diagram of a method of forming a structure on a substrate in accordance with the present disclosure, showing operations of the method according to an illustrative and non-limiting example of the method; and

FIGS. 7A-7E are cross-sectional sides views of a patterned substrate with silicon oxide on its surface, sequentially showing the silicon oxide being removed from the substrate and a silicon-containing material layer being formed on the substrate.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

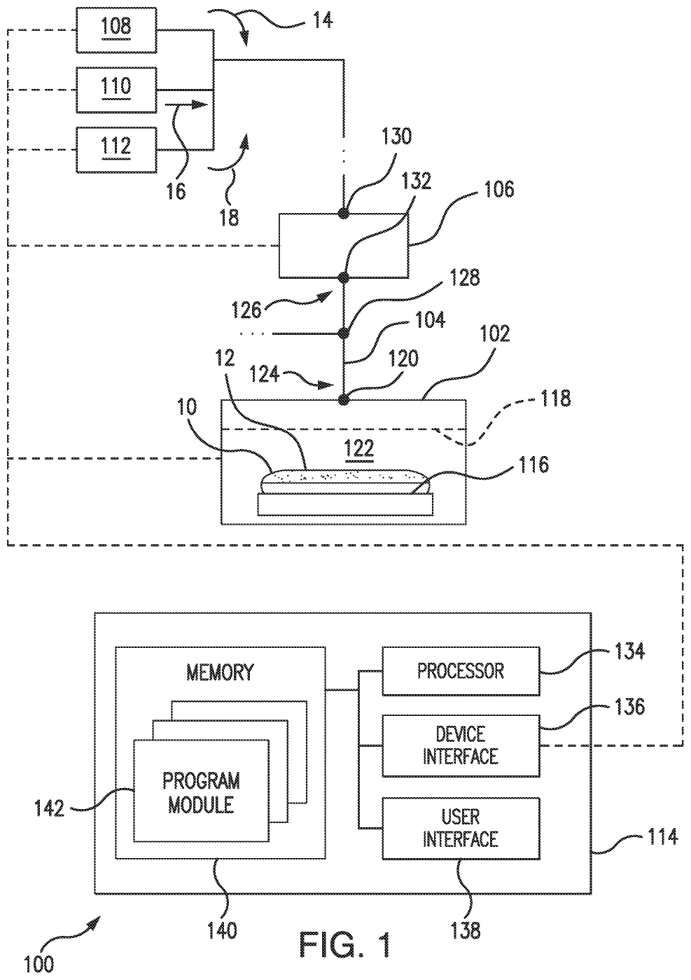

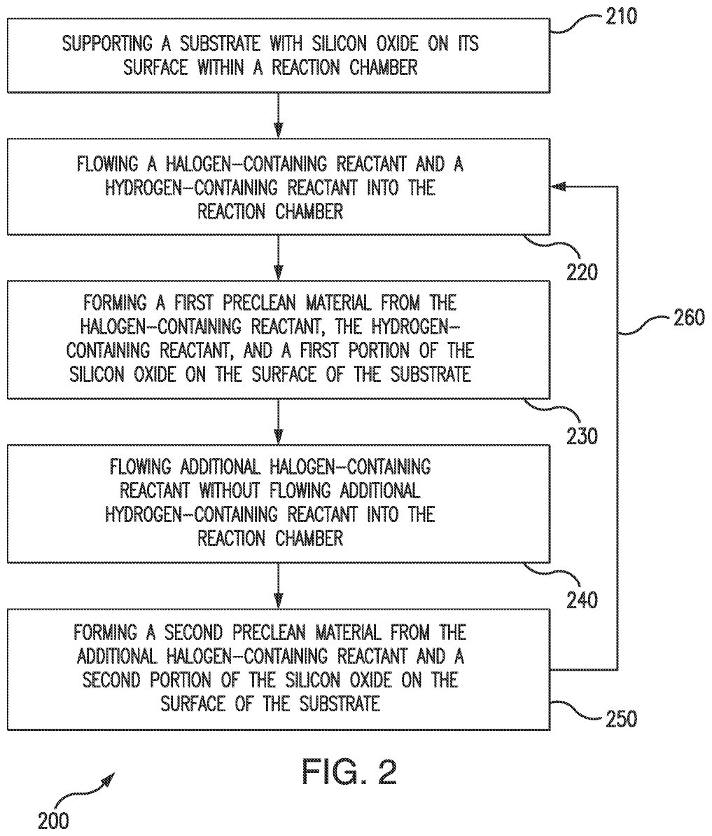

Reference will now be made to the drawings wherein like reference numerals identify similar structural features or aspects of the subject disclosure. For purposes of explanation and illustration, and not limitation, a partial view of an example of semiconductor processing system in accordance with the present disclosure is shown in FIG. 1 and is designated generally by reference character 100. Other examples of semiconductor processing systems, methods of precleaning substrates, and methods of forming structures on precleaned substrates in accordance with the present disclosure, or aspects thereof, are provided in FIGS. 2-7E, as will be described. The systems and methods of the present disclosure may be used for removing silicon oxide from the surfaces of patterned substrates during the fabrication of semiconductor devices, such as during the fabrication of integrated circuit semiconductor devices on patterned substrates with high aspect ratio trenches, though the present disclosure is not limited to any particular type of patterned substrates or to the fabrication of semiconductor devices in general.

Referring to FIG. 1, the semiconductor processing system 100 is shown. The semiconductor processing system 100 includes a reaction chamber 102, a transfer tube 104, and a remote plasma unit 106. The semiconductor processing system 100 also includes a halogen-containing reactant source 108, a hydrogen-containing reactant source 110, and a carrier/purge gas source 112. The semiconductor processing system 100 further includes a controller 114. Although a particular type of semiconductor processing system is shown in FIG. 1 and described herein, i.e., a plasma enhanced chemical vapor deposition (CVD) system, it is to be understood and appreciated that other types of CVD systems, such as atmospheric CVD systems and atomic layer deposition (ALD) systems, may also benefit from the present disclosure.

The reaction chamber 102 has includes a susceptor 116, a showerhead 118, and a reaction chamber gas inlet 120. The susceptor 116 is arranged within an interior 122 of the reaction chamber 102 and is configured to support thereon a substrate 10, e.g., a silicon wafer formed from a semiconductor material. The showerhead 118 is arranged within the interior 122 of the reaction chamber 102, is arranged between the reaction chamber gas inlet 120 and the susceptor 116 and is configured to distribute gas received at the reaction chamber gas inlet 120 to a surface 12 of the substrate 10. The reaction chamber gas inlet 120 couples the interior 122 of the reaction chamber 102 to transfer tube 104.

The transfer tube 104 includes a reaction chamber end 124, a remote plasma unit end 126, and a transfer tube gas inlet 128. The reaction chamber end 124 of the transfer tube 104 is connected to the reaction chamber 102 and is in fluid communication with the reaction chamber gas inlet 120. The transfer tube gas inlet 128 is arranged between the reaction chamber end 124 and the remote plasma unit end 126 of the transfer tube 104 and is connected to at least one of halogen-containing reactant source 108, the hydrogen-containing reactant source 110, and the carrier/purge gas source 112. The remote plasma unit end 126 of the transfer tube 104 is connected to the remote plasma unit 106 and fluidly couples the remote plasma unit 106 to the reaction chamber 102.

The remote plasma unit 106 includes an inlet 130 and an outlet 132. The outlet 132 of the remote plasma unit 106 is connected to the remote plasma unit end 126 of the transfer tube 104. The inlet 130 of the remote plasma unit 106 is connected to at least one of the halogen-containing reactant source 108, the hydrogen-containing reactant source 110, and/or the carrier/purge gas source 112. It is contemplated that the remote plasma unit 106 be configured to activate fluid received by the remote plasma unit 106 at the inlet 130 and provide the activated fluid to the reaction chamber 102 through the outlet 132 and via the transfer tube 104.

The halogen-containing reactant source 108 is connected to the reaction chamber 102, e.g., via the inlet 130 of the remote plasma unit 106 and/or the transfer tube gas inlet 128 and contains a halogen-containing reactant 14. The hydrogen-containing reactant source 108 is also connected to the reaction chamber 102, e.g., also via the inlet 130 of the remote plasma unit 106 and/or the transfer tube gas inlet 128 and contains a hydrogen-containing reactant 16. The carrier/purge gas source 112 is further connected to the reaction chamber 102, e.g., further via the inlet 130 of the remote plasma unit 106 and/or the transfer tube gas inlet 128 and contains an inert gas 18. In certain examples, the halogen-containing reactant 14 includes fluorine (F), such as diatomic fluorine (F₂), a fluorine precursor, or anhydrous hydrogen fluoride (HF). In accordance with certain examples, the hydrogen-containing reactant 16 may include ammonia (NH₃), hydrazine (N₂H₄), an alcohol, or an acid. Examples of suitable alcohols include methanol (CH₃OH) and isopropanol alcohol (C₃H₈O). Examples of suitable acids include acetic acid (C₂H₄O₂). The carrier/purge gas 18 may include nitrogen (N₂), argon (Ar), helium (He), hydrogen (H₂), krypton (Kr), or a mixture thereof.

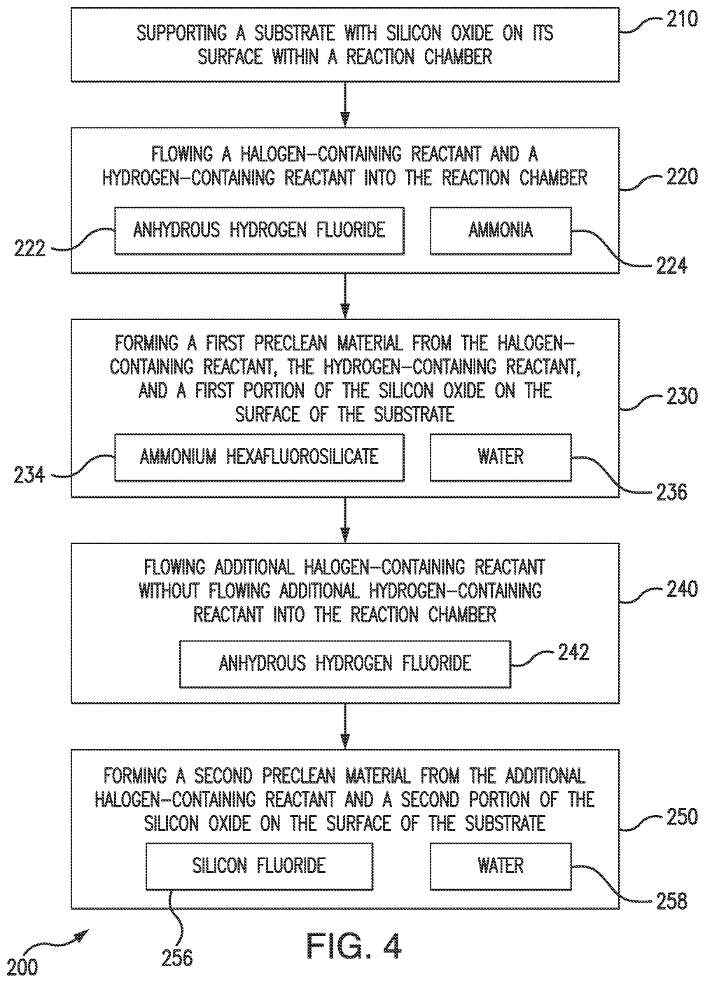

As has been explained above, in some semiconductor processing systems, the chemistry employed to preclean substrates prior to depositing material layers on the substrate may be self-limiting. For example, certain chemistries may create one or more intermediate reaction product that slows (or ceases) the reaction (or reactions) operative to remove silicon oxide from the surface of the substrate. Certain chemistries may also interact with substrate topologies, such as patterned substrates having trenches, silicon oxide removal tending to slow (or stop) within trenches prior to other locations on the substrate due to the tendency of an intermediate reaction product (or products) to collect in the trenches, potentially resulting in uneven silicon oxide removal across the wafer. To limit (or eliminate) the effect that such intermediate reaction products may have ton he removal of silicon oxide from the surface of the substrate 10, e.g., the silicon oxide 20 (shown in FIG. 4A), the controller 114 is provided with instructions to limit the generation of intermediate reaction products during the removal of silicon oxide from substrates.

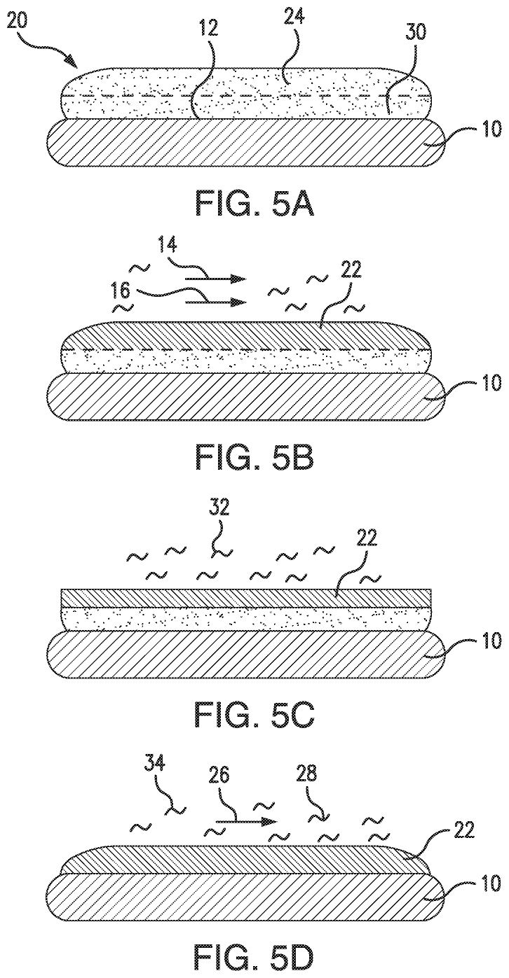

The controller 114 is operatively connected to the semiconductor processing system 100 and includes a processor 134, a device interface 136, a user inter interface 138, and a memory 140. The device interface 136 connects the processor 130 to one or more of the reaction chamber 102, a remote plasma unit 106, the halogen-containing reactant source 108, the hydrogen-containing reactant source 110, and/or the carrier/purge gas source 112, e.g., via a wired or wireless link. The processor 134 is operatively connected to the user interface 138, e.g., to receive user input and/or provide output to a user and is disposed in communication with the memory 140. The memory 140 includes a non-transitory machine-readable medium having a plurality of program modules 142 recorded thereon. The plurality of program modules 142 include instructions that, when read by the processor 134, cause the processor 134 to execute certain operations. Among the operations are operations of a preclean method 200 for removing silicon oxide from a surface of a substrate, e.g., the silicon oxide 20 (shown in FIG. 5A) from the surface 12 (shown in FIG. 5A) of the substrate 10.

With reference to FIG. 2 and FIGS. 5A-5D, the method 200 is shown. As shown with box 210, the substrate 10 (shown in FIG. 5A) with the silicon oxide 20 (shown in FIG. 5A) on its surface 12 (shown in FIG. 5A) is first supported within a reaction chamber, e.g., the reaction chamber 102 (shown in FIG. 1). The halogen-containing reactant 14 (shown in FIG. 5B) and the hydrogen-containing reactant 16 (shown in FIG. 5B) are then flowed into the reaction chamber, as shown with box 220, and a first preclean material 22 (shown in FIG. 5B) formed from the halogen-containing reactant 14, the hydrogen-containing reactant 16, and a first portion 24 of the silicon oxide 20, as shown with box 230. Additional halogen-containing reactant 26 (shown in FIG. 5C) is thereafter flowed into the reaction chamber without additional hydrogen-containing reactant, as shown with box 240, and a second preclean material 28 (shown in FIG. 5C) formed from the additional halogen-containing reactant 26 and a second portion 30 (shown in FIG. 5A) of the silicon oxide 20, as shown with box 250. Advantageously, flowing the additional halogen-containing reactant 26 into the reaction chamber without additional hydrogen-containing reactant allows the second portion 30 of the silicon oxide 20 to be removed without forming additional first preclean material. This limits the amount of the first preclean material formed, limiting (or eliminating) the tendency that the first preclean material 22 to slow (or stop) removal of the silicon oxide 20.

In certain examples, operations 220-250 of the method 200 may be repeated one or more times, as shown with arrow 260. As will be appreciated by those of skill in the art in view of the present disclosure, repeating operations 220-250 allows for tuning the ratio of silicon oxide removed during the formation of the first preclean product 22 and the second preclean material 28, allowing for tuning the preclean method 200. For example, the amount of hydrogen-containing reactant 16 flowed with the halogen-containing reactant 14 may be adjusted according to the effect that the first preclean material 22 may have on the reaction and/or the role that an additional reaction product generated with the first preclean material may have in the generation of the second preclean material 28.

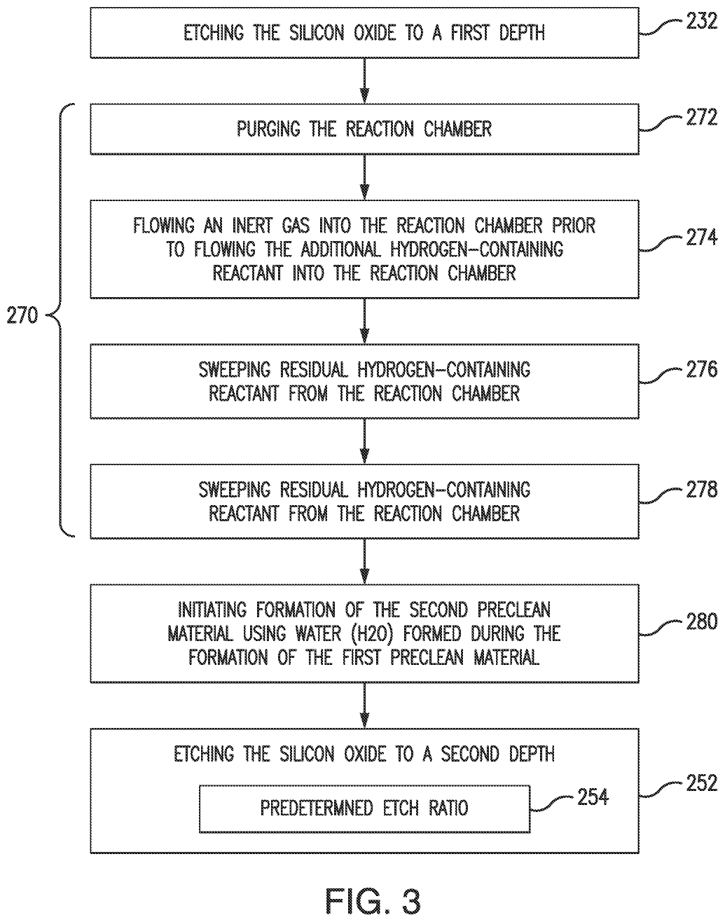

With reference to FIG. 3 and continuing reference to FIGS. 5A-5D, operations of the method 200 are shown according to certain examples. In certain examples, the silicon oxide 20 (shown in FIG. 5A) may be etched during the formation of the first preclean material 22 (shown in FIG. 5B), as shown with box 232. In such examples, the etching process employed to form the first preclean material 22 removes the first portion 24 (shown in FIG. 5A) of the silicon oxide 20 by a reaction between the first halogen-containing reactant 14 (shown in FIG. 5B) and the hydrogen-containing reactant 16 (shown in FIG. 5B) with the silicon oxide 20. As shown with box 252, the silicon oxide 20 may be etched during the formation of the second preclean material 28 (shown in FIG. 5C). In such examples, the etching process employed to form the second preclean material 28 removes the second portion 30 (shown in FIG. 5A) of the silicon oxide 20 by a reaction between the additional halogen-containing reactant 26 (shown in FIG. 5C) and the silicon oxide 20 located below the first portion 24 of the silicon oxide 20.

As shown with box 254, the silicon oxide 20 may be etched at a predetermined ratio during the formation of the first preclean material 22 and the second preclean material 28. For example, a ratio of a second silicon oxide thickness removed during formation of the second preclean material 28 to a first silicon oxide thickness removed during formation of the first preclean material 22 may be greater than 1. In certain examples, the predetermined etch ratio may be between about 2:1 and about 50:1, or between about 3:1 and about 30:1, or between about 5:1 and about 20:1. Advantageously, etch ratios within these ratios allow for initiation of the reaction employed to form the second preclean material 28 (shown in FIG. 5C) using a reaction product generated during the forming of the first preclean material 22 while limiting the effect that the first preclean material 22 may otherwise have on the removal of the second portion 30 (shown in FIG. 5A) of the silicon oxide 20. For example, as shown with box 280, water (H₂O) 32 (shown in FIG. 5C) formed during the formation of the first preclean material 22 may be used to initiate the reaction between the additional halogen-containing reactant 26 (shown in FIG. 5C) and the second portion 30 (shown in FIG. 5A) of the silicon oxide 20, the reaction thereafter being self-sustaining using further water (H₂O) 34 (shown in FIG. 5C) generated during the reaction of the additional halogen-containing reactant 26 and the second portion 30 of the silicon oxide 20.

As shown with bracket 270, in certain examples, the method 200 may include ceasing flow of the hydrogen-containing reactant 16 (shown in FIG. 5B) into the reaction chamber. In certain examples, the reaction chamber may thereafter be purged, e.g., using a flow of the carrier/purge gas 18 (shown in FIG. 1), as shown with box 272. In accordance with certain examples, the carrier/purge gas 18 may be flowed into the reaction chamber prior to flowing the additional halogen-containing reactant 26 (shown in FIG. 5C) into the reaction chamber, as shown with box 274. It is contemplated that, in accordance with certain examples, residual halogen-containing reactant resident within the reaction chamber from the halogen-containing reactant 14 (shown in FIG. 5B) introduced during formation of the first preclean material 22 (shown in FIG. 5B) may be swept from the reaction chamber, e.g., using the carrier/purge gas 18 and/or the additional halogen-containing reactant 26, as shown with box 276. It is also contemplated that, in further examples, residual hydrogen-containing reactant resident within the reaction chamber from the hydrogen-containing reactant 16 (shown in FIG. 5B) introduced during formation of the first preclean material 22 (shown in FIG. 5B) may be swept from the reaction chamber, e.g., using the carrier/purge gas 18 and/or the additional halogen-containing reactant 26, as shown with box 278. As will be appreciated by those of skill in the art in view of the present disclosure, removal of residual hydrogen-containing reactant from the reaction chamber limits (or eliminates) influence effect that the hydrogen-containing reactant may otherwise have on the reaction employed to form the second preclean material 28 (shown in FIG. 5D), providing control of the precleaning operation.

With reference to FIG. 4, the method 200 is shown according to an example employing hydrogen fluoride (HF) and ammonia (NH₃). As shown with box 210, the substrate 10 (shown in FIG. 5A) is supported within a reaction chamber, e.g., the reaction chamber 102 (shown in FIG. 1). The halogen-containing reactant 14 (shown in FIG. 5B) and the hydrogen-containing reactant 16 (show in FIG. 5B) are flowed in to the reaction chamber, as shown with box 220. As shown with box 222, it is contemplated that the halogen-containing reactant 14 include hydrogen fluoride (HF). As shown with box 224, it is also contemplated that the hydrogen-containing reactant 16 include ammonia (NH₃). In certain examples, the halogen-containing reactant 14 and the hydrogen-containing reactant 16 may consist essentially of anhydrous hydrogen fluoride (HF) and ammonia (NH₃). In accordance with certain examples, the halogen-containing reactant 14 and the hydrogen-containing reactant 16 may consist of anhydrous hydrogen fluoride (HF) and ammonia (NH₃).

As shown with box 230, the first preclean material 22 (shown in FIG. 5B) is formed from the halogen-containing reactant 14, the hydrogen-containing reactant 16, and the first portion 24 (shown in FIG. 5A) of the silicon oxide 20 (shown in FIG. 5A). More specifically, the anhydrous hydrogen fluoride (HF) reacts with the ammonia (NH₃) and the first portion 24 of the silicon oxide 20 to form ammonium hexafluorosilicate ((NH₄)₂SiF₆) and the water (H₂O) 32 (shown in FIG. 5C), as shown with box 234 and box 236. Without being bound by a particular theory or mode of operation, it is believed that the anhydrous hydrogen fluoride (HF) reacts with the ammonia (NH₃) to form ammonium fluoride (NH₄F). The ammonium fluoride (NH₄F) in turn removes the first portion 24 of the silicon oxide 20 by reacting with the silicon oxide to form ammonium hexafluorosilicate ((NH₄)₂SiF₆) and water (H₂O) that stays on the silicon oxide surface.

As will also be appreciated by those of skill in the art in view of the present disclosure, the film formed by the ammonium hexafluorosilicate ((NH₄)₂SiF₆) may limit access to the silicon oxide underlaying the film. As the film formed by the ammonium hexafluorosilicate ((NH₄)₂SiF₆ thickens, access is increasingly limited, potentially slowing (or stopping) the reaction, as has been explained above. To limit (or eliminate) the tendency of the film formed by the ammonium hexafluorosilicate ((NH₄)₂SiF₆) to slow (or stop) the reaction, it is contemplated that the flow of ammonia (NH₃) to the reaction chamber be stopped. Additional anhydrous hydrogen fluoride (HF) is thereafter flowed into the reaction chamber without additional ammonia (NH₃), as shown with box 240 and box 242, the water (H₂O) generated during the forming of the first preclean material initiating a reaction between the additional anhydrous hydrogen-fluoride (HF). In this respect it is contemplated that the water (H₂O) 32 be available to the additional hydrogen fluoride (HF) in the form of surface-adsorbed water (H₂O) molecules, surface water (H₂O), or water (H₂O) vapor within the reaction chamber.

As shown with box 250, the additional anhydrous hydrogen fluoride (HF) reacts with the second portion 30 (shown in FIG. 5A) of the silicon oxide 20 (shown in FIG. 5A) to form the second preclean material 28 (shown in FIG. 5D) and additional water (H₂O) 34 (shown in FIG. 5D). In this respect the water (H₂O) 32 formed in conjunction with the formation of the first preclean material 22 serve to initiate reaction of the additional anhydrous hydrogen fluoride (HF) with the second portion 30 of the silicon oxide 20, the additional anhydrous hydrogen fluoride (HF) and silicon oxide forming additional silicon tetrafluoride (SiF₄) as the second preclean material 28 and the additional water (H₂O) 34, as shown with box 256 and box 258. In this respect the water (H₂O) 32 may operate to dissociate the hydrogen fluoride (HF) into H+ and F− cations and anions, respectively, initiating removal of the second portion 30 of the silicon oxide 20. In certain examples, the additional silicon tetrafluoride (SiF₄) is formed in the absence of ammonia (NH₃), the silicon tetrafluoride (SiF₄) remaining as a gas and therefore not slowing (or stopping) the reaction by further limiting access to the silicon oxide 20 located on the surface 12 of the substrate 10 and below the first preclean material 22 during the reaction.

In certain examples, one or more of the halogen-containing reactant, the hydrogen-containing reactant, and/or the additional halogen-containing reactant may be activated by a plasma source. For example, one or more of the anhydrous hydrogen fluoride (HF), the ammonia (NH₃) and/or the additional anhydrous hydrogen fluoride (HF) may be activated by a remote plasma unit, e.g., the remote plasma unit 106 (shown in FIG. 1), to generate one or more activated reactant species, e.g., generate charged ions, and/or neutral atoms and/or radicals. In accordance with certain examples, one or more of the halogen-containing reactant, the hydrogen-containing reactant, and/or the additional halogen-containing reactant may not be activated by the plasma source. It is also contemplated a carrier gas maybe included with one or more of the halogen-containing reactant, the hydrogen-containing reactant and/or the additional halogen-containing reactant flowed to the reaction chamber. In certain examples, the carrier gas may be activated by the plasma source. In accordance with certain examples, the carrier gas may not be activated by the plasma source.

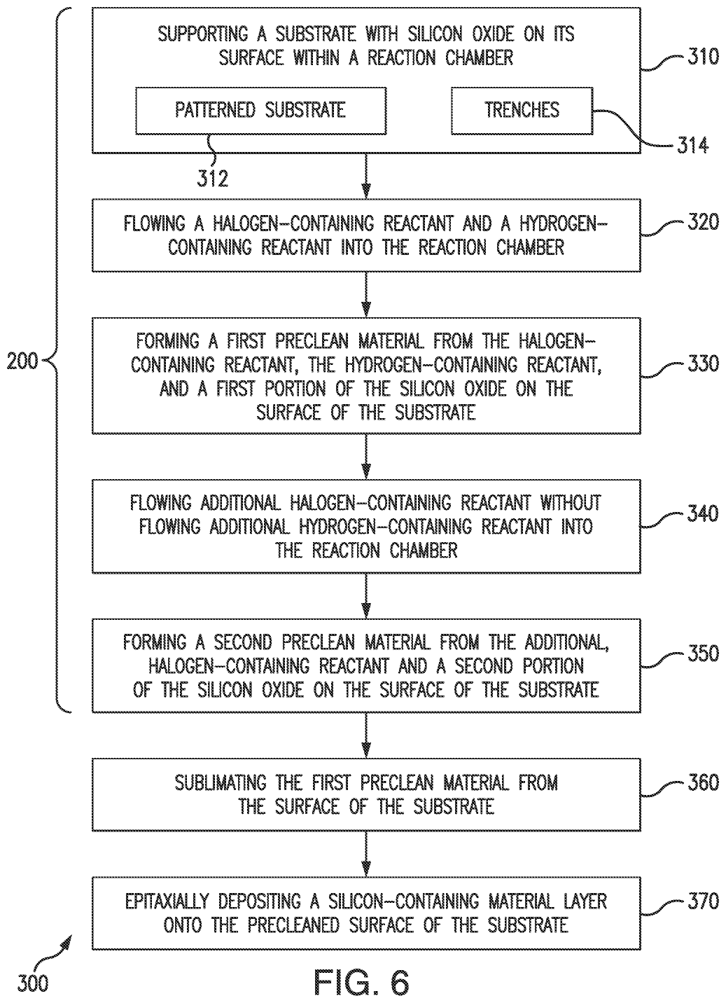

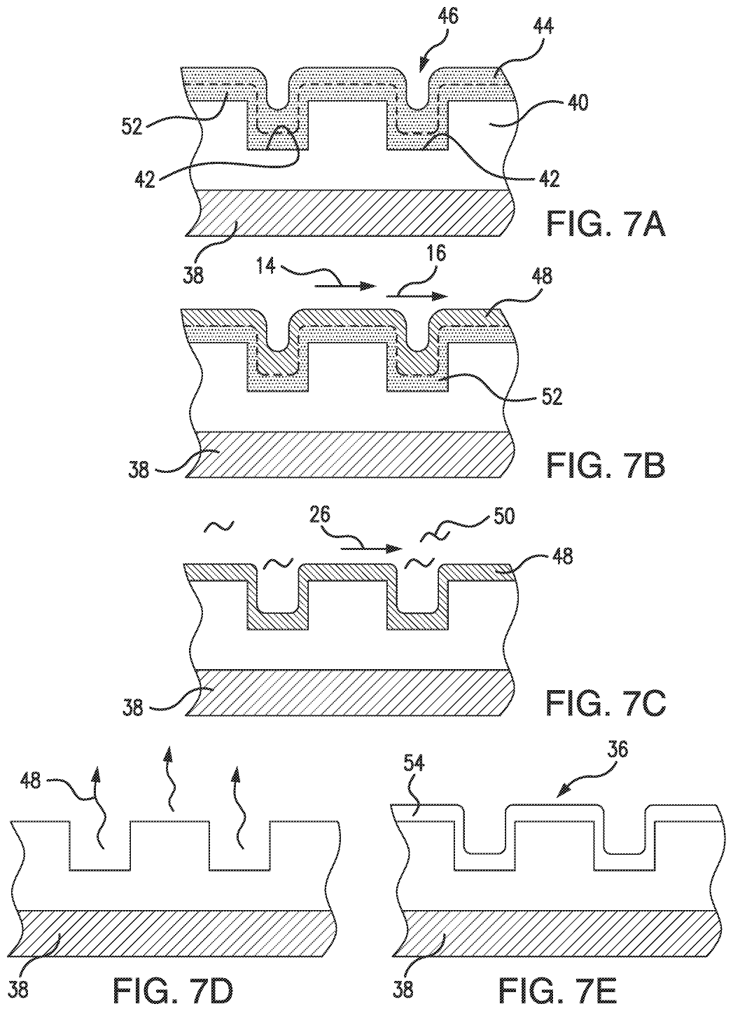

With reference to FIGS. 6 and 7A-7E, a method 300 of forming a structure, e.g., an integrated circuit semiconductor device 36 (shown in FIG. 7E), is shown. As shown with box 310, a substrate, e.g., a substrate 38 (shown in FIG. 7A), is supported within a reaction chamber, e.g., the reaction chamber 102 (shown in FIG. 1). In certain examples, a pattern 40 (shown in FIG. 7A) may be defined on a surface of the substrate 38, as shown with box 312. In accordance with certain examples, the substrate 38 may have a plurality of trenches 42 defined on the surface the substrate, e.g., trenches 42 (shown in FIG. 7A), as shown with box 314. In certain examples, the plurality of trenches 42 may have a high aspect ratio. For example, the plurality of trenches 42 may each have a depth that is greater than its width. In certain examples, the high aspect ratio include a depth-to-width ratio that is between about 2:1 and about 50:1, or is between about 10:1 and about 40:1, or is between about 25:1 and about 40:1.

As shown with bracket 200, once supported in the reaction chamber, the substrate 38 is precleaned, e.g., to remove silicon oxide 46 on the substrate 38 and disposed at least partially within the pattern 40. It is contemplated that the substrate 38 be cleaned using the preclean method 200. In this respect it is contemplated that the halogen-containing reactant 14 (shown in FIG. 7B) and the hydrogen-containing reactant 16 (shown in FIG. 7B) be flowed into the reaction chamber, as shown with box 320. Once within the reaction chamber, the halogen-containing reactant 14 and the hydrogen-containing reactant 16 react with a first portion 44 (shown in FIG. 7A) of silicon oxide 46 to form a first preclean material 48 (shown in FIG. 7B), as shown with box 330. The additional halogen-containing reactant 26 (shown in FIG. 7C) is then flowed into the reaction chamber without additional hydrogen-containing reactant, as shown with box 340, and a second preclean material 50 formed on the surface of the substrate 38 using the additional halogen-containing reactant 26 and a second portion 52 (shown in FIG. 7A) of the silicon oxide 46, as shown with box 350.

As shown with box 360, the first preclean material 48 is thereafter removed from the surface of the substrate 38. It is contemplated that the first preclean material 48 be sublimated from the surface of the substrate, e.g., by heating the substrate, as shown in FIG. 7D. As shown with box 370, a silicon-containing layer 54 is thereafter epitaxially deposited onto the precleaned surface of the substrate 38. In certain examples, the silicon-containing layer 54 may be a silicon layer. In accordance with certain examples, the silicon-containing layer 54 may include germanium. It is also contemplated that, in accordance with certain examples, that the silicon-containing layer 54 may include a dopant, such as an n-type or a p-type dopant. The silicon-containing layer 54 may be deposited in another reaction chamber, e.g., by transferring the substrate 38 once precleaned from the reaction chamber 102 (shown in FIG. 1) to another reaction chamber of the semiconductor processing system 100 (shown in FIG. 1).

Before certain deposition operations, e.g., the epitaxial deposition of silicon-containing layers, native oxide on silicon and silicon germanium surfaces may require cleaning and/or removal for high-quality epitaxial films. The need for cleaning may be particularly acute at technology nodes employing high aspect ratios and/or different dielectric films on patterned substrates or wafers. For example, native oxide located on the bottom surfaces and side walls of deep trenches may require complete cleaning. Low-k dielectric materials may limit the employment of certain types of etching processes, such as certain plasma etching processes and chemistries. The cleaning chemistries may require high selectivity to various dielectric films located on patterned substrates.

In certain examples described herein, a catalyst is employed to initiate the etching process, and etching is thereafter accomplished using an etchant subsequent to initiation of the etching process. In accordance with certain examples, relatively small amounts of anhydrous hydrogen fluoride (HF) and ammonia (NH₃) are co-flowed with one another to the reaction chamber, e.g., for a relative short period of time, and remove a limited amount of the silicon oxide to be cleaned during the cleaning process. In further examples, the anhydrous hydrogen fluoride (HF) and ammonia (NH₃) are thereafter purged from the reaction chamber, e.g., using an inert gas such as argon (Ar). It is contemplated that additional anhydrous hydrogen fluoride (HF) thereafter be introduced in to the reaction chamber, and that additional silicon oxide is thereafter removed from substrate, e.g., by removing a second, larger portion of silicon oxide from the substrate.

Advantageously, as appreciated by the application, cleaning silicon oxide from substrates does not require a continuous supply of catalyst where a byproduct of the catalyst-initiated reaction may serve to continue the reaction, e.g., where surface moisture and or water (H₂O) generated by catalyst-assisted reaction is sufficient for to continue subsequent etching using additional etchant without additional catalysts. This can be particularly advantageous where high-k dielectric materials located on the surface of the substrate may be damaged by the catalyst or a catalyst-generated intermediate reaction intermediary. For example, in certain examples, very limited amounts of reaction byproducts like ammonium hexafluorosilicate (NH₄)₂SiF₆ are produced, facilitating high aspect ratio epi precleaning by limiting the tendency of such materials to fill trenches on the substrate, and otherwise preventing and the lower portions of the trenches from being cleaned. Limiting the generation of such reaction byproducts may also improve selectivity to other films on the surface of the substrate, e.g., to SiN, SiOC, and/or Al₂O₃ films.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

### PARTS LIST

10 Substrate
12 Surface
14 Halogen-Containing Reactant
16 Hydrogen-Containing Reactant
18 Carrier/Purge Gas
20 Silicon Oxide
22 First Preclean Material
24 First Portion
26 Additional Halogen-Containing Reactant
28 Second Preclean Material
30 Second Portion
32 Water
34 Water
36 Semiconductor Device
38 Substrate
40 Pattern
42 Trenches
44 First Portion
46 Silicon Oxide
48 First Preclean Material
50 Second Preclean Material
52 Second Portion
54 Silicon-Containing Layer
100 Semiconductor Processing System
102 Reaction Chamber
104 Transfer Tube
106 Remote Plasma Unit
108 Halogen-Containing Reactant Source
110 Hydrogen-Containing Reactant Source
112 Carrier/Purge Gas Source
114 Controller
116 Susceptor
118 Showerhead
120 Reaction Chamber Gas Inlet
122 Interior
124 Reaction Chamber End
126 Remote Plasma Unit End
128 Transfer Tube Gas Inlet
130 Inlet
132 Outlet
134 Processor
136 Device Interface
138 User Interface
140 Memory
142 Program Modules
200 Method
210 Box
220 Box
222 Box
224 Box
230 Box
232 Box
234 Box
236 Box
240 Box
242 Box
250 Box
252 Box
254 Box
256 Box
258 Box
260 Arrow
270 Bracket
272 Box
274 Box
276 Box
278 Box
280 Box
300 Method
310 Box
312 Box
314 Box
320 Box
330 Box
340 Box
350 Box
360 Box

1. A method of precleaning a substrate, comprising:
supporting a substrate with silicon oxide on its surface within a reaction chamber of a semiconductor processing system;
flowing a halogen-containing reactant and a hydrogen-containing reactant into the reaction chamber;
forming a first preclean material from the halogen-containing reactant, the hydrogen-containing reactant, and a first portion of the silicon oxide on the surface of the substrate;
flowing additional halogen-containing reactant without flowing additional hydrogen-containing reactant into the reaction chamber; and
forming a second preclean material from the additional halogen-containing reactant and a second portion of the silicon oxide on the surface of the substrate.

2. The method of claim 1, further comprising epitaxially depositing a silicon-containing material layer onto the precleaned surface of the substrate.

3. The method of claim 1, wherein flowing the halogen-containing reactant and the hydrogen-containing reactant into the reaction chamber comprises flowing anhydrous hydrogen fluoride (HF) and at least one of ammonia (NH₃), hydrazine (N₂H₄), methanol (CH₃OH), isopropanol (C₃H₈O), or acetic acid (C₂H₄O₂) into the reaction chamber.

4. The method of claim 1, wherein flowing the additional halogen-containing reactant into the reaction chamber comprises flowing anhydrous hydrogen fluoride (HF) into the reaction chamber without flowing additional hydrogen-containing reactant into the reaction chamber.

5. The method of claim 1, wherein forming the first preclean material comprises forming ammonium hexafluorosilicate ((NH₄)₂SiF₆) and water (H₂O) from the halogen-containing reactant, the hydrogen-containing reactant, and the silicon oxide on the surface of the substrate.

6. The method of claim 1, wherein forming the second preclean material from the halogen-containing reactant and the silicon oxide comprises forming silicon fluoride (SiF₄) and water (H₂O) from the halogen-containing reactant and the silicon oxide on the surface of the substrate.

7. The method of claim 1, further comprising sublimating the first preclean material from the surface of the substrate subsequent to forming the second preclean material from the additional halogen-containing reactant and the silicon oxide on the surface of the substrate.

8. The method of claim 1, wherein the substrate comprises a patterned substrate having a plurality of recesses or trenches with a high aspect ratio.

9. The method of claim 1, wherein forming the second preclean material comprises initiating formation of the second preclean material using water (H₂O) formed during the formation of the first preclean material.

10. The method of claim 1, further comprising flowing an inert gas into the reaction chamber prior to flowing the additional halogen-containing reactant into the reaction chamber and subsequent to forming the first preclean material from the halogen-containing reactant and the hydrogen-containing reactant.

11. The method of claim 1, further comprising sweeping residual halogen-containing reactant from the reaction chamber prior to flowing the additional halogen-containing reactant into the reaction chamber.

12. The method of claim 1, further comprising sweeping residual hydrogen-containing reactant from the reaction chamber prior to flowing the additional halogen-containing reactant into the reaction chamber.

13. The method of claim 1, wherein forming the first preclean material comprises etching the silicon oxide to a first depth; wherein forming the second preclean material comprises etching the silicon oxide to a second depth; and wherein a ratio of the second depth to the first depth is between about 2:1 and about 50:1, or is between about 3:1 and about 30:1, or is between about 5:1 and about 20:1.

14. The method of claim 1, further comprising ceasing formation of the first preclean material by purging the reaction chamber prior to flowing the additional halogen-containing reactant into the reaction chamber.

15. A method of forming a structure, comprising:
precleaning a substrate using the method of claim 1, wherein the substrate comprises a patterned substrate having a plurality of recesses or trenches with a high aspect;
sublimating the first preclean material from the surface of the substrate subsequent to forming the second preclean material from the additional halogen-containing reactant and silicon oxide on the surface of the substrate; and
epitaxially depositing a silicon-containing material layer onto the surface of the substrate subsequent to e sublimating the first preclean material from the surface of the substrate.

16. The method of claim 15, wherein flowing the halogen-containing reactant and the hydrogen-containing reactant into the reaction chamber comprises flowing anhydrous hydrogen fluoride (HF) and ammonia (NH₃) into the reaction chamber, and wherein flowing the additional halogen-containing reactant into the reaction chamber comprises flowing anhydrous hydrogen fluoride (HF) into the reaction chamber without flowing additional hydrogen-containing reactant into the reaction chamber.

17. The method of claim 15, wherein forming the first preclean material comprises forming ammonium hexafluorosilicate ((NH₄)₂SiF₆) and water (H₂O) from the halogen-containing reactant, the hydrogen-containing reactant, and the silicon oxide on the surface of the substrate, and wherein forming the second preclean material from the halogen-containing reactant and the silicon oxide comprises forming silicon fluoride (SiF₄) and water (H₂O) from the halogen-containing reactant and the silicon oxide on the surface of the substrate.

18. A semiconductor processing system, comprising:
a gas system configured to flow a halogen-containing reactant and a hydrogen-containing reactant to a reaction chamber;
a reaction chamber connected to the gas system and configured to support a substrate with silicon oxide on its surface; and
a controller operatively associated with the gas system and the reaction chamber, the controller responsive to instruction recorded on a non-transitory machine-readable medium to:
support a substrate having silicon oxide on its surface within the reaction chamber;
flow a halogen-containing reactant and a hydrogen-containing reactant into the reaction chamber;
form a first preclean material from the halogen-containing reactant, the hydrogen-containing reactant, and a first portion of the silicon oxide on the surface of the substrate;
flow additional halogen-containing reactant without additional hydrogen-containing reactant into the reaction chamber; and
form a second preclean material from the additional halogen-containing reactant and a second portion of the silicon oxide on the surface of the substrate.

19. The semiconductor processing system of claim 18, wherein the instructions further cause the controller to:
flow anhydrous hydrogen fluoride (HF) and ammonia (NH₃) into the reaction chamber to form the first preclean material; and
flow additional anhydrous hydrogen fluoride (HF) into the reaction chamber without flowing additional ammonia into the reaction chamber.

20. The semiconductor processing system of claim 19, wherein the instructions further cause the controller to:
form ammonium hexafluorosilicate ((NH₄)₂SiF₆) as the first preclean material in conjunction with and water (H₂O) from the halogen-containing reactant, the hydrogen-containing reactant, and the silicon oxide on the surface of the substrate;
cease formation of the ammonium hexafluorosilicate ((NH₄)₂SiF₆) by purging the reaction chamber prior to flowing the additional anhydrous hydrogen fluoride (HF) into the reaction chamber;
form silicon fluoride (SiF₄) as the second preclean material in conjunction with water (H₂O) from the halogen-containing reactant and the silicon oxide on the surface of the substrate; and
sublimate the ammonium hexafluorosilicate ((NH₄)₂SiF₆) from the surface of the substrate subsequent to forming the silicon fluoride (SiF₄) using the anhydrous hydrogen fluoride (HF) and silicon oxide on the surface of the substrate.
